(19) United States
(12) Patent Application Publication
(10) Pub. No.: US 2026/0177762 A1
(43) Pub. Date: Jun. 25, 2026

(54) TOP-SIDE OPTICAL COUPLERS FOR ADVANCED PACKAGE ARCHITECTURES

(71) Applicant: Lightmatter, Inc., Boston, MA (US)

(72) Inventors: Omkar Karhade, Chandler, AZ (US); Stefan Pfnuer, Scotts Valley, CA (US); Sandeep Sane, Chandler, AZ (US); Sufi Ahmed, Chandler, AZ (US); Mitul Modi, Phoenix, AZ (US); Jessie Rosenberg, Bedford, MA (US); Binoy Shah, Niskayuna, NY (US); Shreyash Bhattarai, Sunnyvale, CA (US)

(73) Assignee: Lightmatter, Inc., Boston, MA (US)

(21) Appl. No.: 19/425,834

(22) Filed: Dec. 18, 2025

Related U.S. Application Data
(60) Provisional application No. 63/736,532, filed on Dec. 19, 2024.
(60) Provisional application No. 63/756,005, filed on Feb. 7, 2025.
(60) Provisional application No. 63/762,736, filed on Feb. 25, 2025.
(60) Provisional application No. 63/766,294, filed on Mar. 3, 2025.
(60) Provisional application No. 63/780,130, filed on Mar. 28, 2025.
(60) Provisional application No. 63/925,412, filed on Nov. 25, 2025.

(51) Int. Cl. G02B 6/42; H10W 90/28

(52) U.S. Cl. CPC G02B 6/4214; G02B 6/4206; G02B 6/4212; G02B 6/4239; G02B 6/4244; G02B 6/4245; H10W 90/28

(57) ABSTRACT

A device may include an electronic-photonic assembly comprising: a photonic integrated circuit (PIC) comprising a waveguide defining a waveguide plane, an electronic integrated circuit (EIC) attached to the PIC; and an encapsulant at least partially encapsulating the EIC. A device may include an optical coupler attached to the PIC, wherein the optical coupler is configured to collimate, in a first direction that is angled relative to the waveguide plane, light emitted by the PIC upon being guided by the waveguide. A device may include an optical assembly comprising a detachable plug and a fiber attached to the detachable plug, wherein the optical assembly is positioned to receive the collimated light from the optical coupler.

### CROSS-REFERENCE TO RELATED APPLICATIONS

This application claims the benefit of U.S. Provisional Application Ser. No. 63/736,532, filed on Dec. 19, 2024, under Attorney Docket No. L0858.70112US00 and entitled “EXPOSED COUPLER MOLDED ARCHITECTURE FOR OPTICAL DEVICES;” U.S. Provisional Application Ser. No. 63/756,005, filed on Feb. 7, 2025, under Attorney Docket No. L0858.70112US01 and entitled “OPTICAL COUPLERS FOR OPTICAL DEVICES;” U.S. Provisional Application Ser. No. 63/762,736, filed on Feb. 25, 2025, under Attorney Docket No. L0858.70112US02 and entitled “MOLDED COLLIMATED LENS ARCHITECTURE FOR 3D OPTICAL PACKAGES;” U.S. Provisional Application Ser. No. 63/766,294, filed on Mar. 3, 2025, under Attorney Docket No. L0858.70112US03 and entitled “EXPOSED COUPLER MOLDED ARCHITECTURE FOR OPTICAL DEVICES;” U.S. Provisional Application Ser. No. 63/780,130, filed on Mar. 28, 2025, under Attorney Docket No. L0858.70112US04 and entitled “EXPOSED COUPLER MOLDED ARCHITECTURE FOR OPTICAL DEVICES;” U.S. Provisional Application Ser. No. 63/925,412, filed on Nov. 25, 2025, under Attorney Docket No. L0858.70112US05 and entitled “EXPOSED COUPLER MOLDED ARCHITECTURE FOR OPTICAL DEVICES,” each of which is hereby incorporated herein by reference in its entirety.

### BACKGROUND

As data communications systems continue to scale to meet ever-increasing bandwidth demands, the limitations of traditional copper data channels have become increasingly apparent. Signal attenuation, crosstalk, and electromagnetic interference pose significant challenges, which can be partially mitigated through techniques such as equalization, coding, and shielding. However, these approaches often require substantial power, complexity, and cable bulk, offering only modest improvements in reach and limited scalability. Optical communication has emerged as a promising successor to copper links, offering the potential to overcome these limitations.

### BRIEF SUMMARY

In some aspects, the techniques described herein relate to a photonic device, including: an electronic-photonic assembly including: a photonic integrated circuit (PIC) including a waveguide defining a waveguide plane; an electronic integrated circuit (EIC) attached to the PIC; and an encapsulant at least partially encapsulating the EIC; an optical coupler attached to the PIC, wherein the optical coupler is configured to collimate, in a first direction that is angled relative to the waveguide plane, light emitted by the PIC upon being guided by the waveguide; and an optical assembly including a detachable plug and a fiber attached to the detachable plug, wherein the optical assembly is positioned to receive the collimated light from the optical coupler.

In some aspects, the techniques described herein relate to a photonic device, wherein the optical assembly is disposed on a top surface of the encapsulant.

In some aspects, the techniques described herein relate to a photonic device, wherein the optical coupler includes: a reflective portion configured to reflect the light emitted by the PIC in the first direction; and a convex portion configured to perform the collimation.

In some aspects, the techniques described herein relate to a photonic device, wherein the PIC defines a recess near an end of the waveguide, and wherein the reflective portion extends into the recess.

In some aspects, the techniques described herein relate to a photonic device, further including an index-matching epoxy disposed in the recess.

In some aspects, the techniques described herein relate to a photonic device, wherein the reflective portion includes a surface that is angled by approximately 45° relative to the waveguide plane.

In some aspects, the techniques described herein relate to a photonic device, wherein the optical coupler extends through the encapsulant.

In some aspects, the techniques described herein relate to a photonic device, wherein the PIC further includes a grating coupler optically coupled to the waveguide and configured to emit light received from the waveguide in the first direction, wherein the optical coupler is configured to collimate the light emitted by the grating coupler.

In some aspects, the techniques described herein relate to a photonic device, further including an index-matching epoxy disposed between the optical coupler and the optical assembly.

In some aspects, the techniques described herein relate to a photonic device, wherein the index-matching epoxy has a surface that is co-planar with a surface of the encapsulant.

In some aspects, the techniques described herein relate to a photonic device, further including a glass plate disposed between the index-matching epoxy and the optical assembly, wherein the glass plate has a surface that is co-planar with a surface of the encapsulant.

In some aspects, the techniques described herein relate to a photonic device, including: a chip-on-wafer-on-substrate (CoWoS) package including an interposer and an electronic-photonic assembly disposed on the interposer, the electronic-photonic assembly including: a photonic integrated circuit (PIC) having a first side and a second side opposite the first side, wherein the first side of the PIC is attached to the interposer, and wherein the PIC includes a waveguide defining a waveguide plane; a first electronic integrated circuit (EIC) attached to the second side of the PIC; and a first encapsulant at least partially surrounding the first EIC; an optical coupler attached to the PIC, wherein the optical coupler is configured to collimate, in a first direction that is angled relative to the waveguide plane, light emitted by the PIC upon being guided by the waveguide; an optical assembly including a detachable plug and a fiber attached to the detachable plug, wherein the optical assembly is positioned to receive the collimated light from the optical coupler; and a second encapsulant at least partially surrounding the electronic-photonic assembly.

In some aspects, the techniques described herein relate to a photonic device, further including a second EIC and a third EIC disposed on the interposer, wherein the interposer places the electronic-photonic package in electrical communication with at least one between the second and third EICs.

In some aspects, the techniques described herein relate to a photonic device, wherein: the first EIC includes electronic circuitry configured to control active photonic circuitry of the PIC, the second EIC includes a processing chip, and the third EIC includes a high-bandwidth memory.

In some aspects, the techniques described herein relate to a photonic device, wherein the optical coupler includes: a reflective portion configured to reflect the light emitted by the PIC in the first direction; and a convex portion configured to perform the collimation.

In some aspects, the techniques described herein relate to a photonic device, wherein the PIC defines a recess near an end of the waveguide, and wherein the reflective portion extends into the recess.

In some aspects, the techniques described herein relate to a photonic device, wherein the PIC further includes a grating coupler optically coupled to the waveguide and configured to emit light received from the waveguide in the first direction, wherein the optical coupler is configured to collimate the light emitted by the grating coupler.

In some aspects, the techniques described herein relate to a method for fabricating a photonic device, including: forming an electronic-photonic assembly by attaching an electronic integrated circuit (EIC) to a photonic integrated circuit (PIC) having a waveguide; attaching an optical coupler including a collimator to the PIC so that the collimator is optically coupled to the waveguide; forming an encapsulant by overmolding the electronic-photonic assembly; exposing the optical coupler to air by removing at least a portion of the encapsulant that covers the optical coupler; and attaching an optical assembly to the electronic-photonic assembly, the optical assembly including a detachable plug and a fiber attached to the detachable plug.

In some aspects, the techniques described herein relate to a method, wherein the PIC defines a recess near an end of the waveguide, and wherein attaching the optical coupler to the PIC includes placing the optical coupler in the recess.

In some aspects, the techniques described herein relate to a method, wherein removing at least a portion of the encapsulant that covers the optical coupler includes performing a grinding process on the electronic-photonic assembly.

### BRIEF DESCRIPTION OF DRAWINGS

Various aspects and embodiments of the application will be described with reference to the following figures. It should be appreciated that the figures are not necessarily drawn to scale. Items appearing in multiple figures are indicated by the same reference number in the figures in which they appear.

FIG. 1A is a side view of a photonic device including an electronic-photonic assembly, an optical coupler and a detachable plug holding an optical fiber, in accordance with some embodiments.

FIG. 1B is a side view of a portion of the photonic device of FIG. 1A, in accordance with some embodiments.

FIG. 2A is a side view of a package including an electronic-photonic assembly disposed on an interposer and an optical coupler attached to the electronic-photonic assembly, in accordance with some embodiments.

FIG. 2B is a side view illustrating a potential implementation of the optical coupler of FIG. 2A, in accordance with some embodiments.

FIG. 2C is a side view illustrating the optical coupler of FIG. 2B in additional detail, in accordance with some embodiments.

FIG. 2D is a side view illustrating an alternative implementation of the optical coupler of FIG. 2A in additional detail, in accordance with some embodiments.

FIG. 2E is a side view of another package including an electronic-photonic assembly disposed on an interposer, where the interposer is configured as a bridge, in accordance with some embodiments.

FIG. 3A is a side view of a package including an electronic-photonic assembly having a grating coupler, an optical coupler and a detachable plug holding an optical fiber, in accordance with some embodiments.

FIG. 3B is a side view of another package including an electronic-photonic assembly including a grating coupler, an optical coupler and a detachable plug holding an optical fiber, in accordance with some embodiments.

FIGS. 4A-4I are cross sectional views illustrating a process for fabricating a photonic device, in accordance with some embodiments. In the fabrication step corresponding to FIG. 4A, a photonic integrated circuit (PIC) is obtained. In the fabrication step corresponding to FIG. 4B, the substrate of the PIC is ground. In the fabrication step corresponding to FIG. 4C, conductive pads are formed on the ground surface of the PIC. In the fabrication step corresponding to FIG. 4D, application-specific integrated circuits (ASICs) are attached to the PIC. In the fabrication step corresponding to FIG. 4E, an underfill is formed between the ASICs and the PIC. In the fabrication step corresponding to FIG. 4F, an optical coupler is attached to the PIC. In the fabrication step corresponding to FIG. 4G, overmolding is performed on the photonic device to form an encapsulant. In the fabrication step corresponding to FIG. 4H, part of the encapsulant is removed. In the fabrication step corresponding to FIG. 4I, an optical assembly is attached to the PIC.

### DETAILED DESCRIPTION

The inventors have recognized and appreciated that despite the advantages of optical communication systems, conventional techniques for optical coupler integration face their own set of challenges. Conventional approaches either rely on non-pluggable optical coupler attachments or non-molded architectures that are susceptible to mechanical damage. Non-pluggable designs lack the ability to replace non-functioning fiber attachments, while non-molded architectures leave the photonic integrated circuit (PIC) area exposed, increasing the risk of mechanical damage due to the thin die thickness, typically ranging from 50 to 100 μm.

The inventors have further recognized and appreciated that molded 3D stack architectures are preferred for manufacturing due to their mechanical robustness and compatibility with industry-standard processes. However, traditional molded designs do not offer pluggability, as the optical coupler becomes non-functional if molding gets on the optical coupler. Some embodiments address these challenges to enable high-performance, scalable, and cost-effective optical communication systems.

Chip-on-Wafer-on-Substrate (CoWoS) is an advanced packaging technology that enables integration of multiple chips (e.g., processors, memories and accelerators) on a silicon interposer with an extremely high density of interconnects. CoWoS is used extensively in advanced computer networks because it provides very high bandwidth, large package sizes and seamless integration of high-bandwidth memory.

Described herein are photonic devices that are compatible with existing interposer-based packaging technologies, such as CoWoS. The inventors have recognized and appreciated that the bandwidth of conventional interposer-based packages can be further extended using photonic interfaces. Optical transmission has several advantages over conventional electrical transmission. Photons do not suffer from the same physical limits as electrons when transporting information, especially at high data rates and over long distances. Electrical bandwidth decreases as frequency increases due to the inherent impedance associated with electrical interconnects. Further, electrical loss scales exponentially with distance. By contrast, optical links are characterized by enormous available bandwidth over very long distances. Further advantages include reduced power consumption, immunity to electromagnetic interference and reduced latency.

However, integrating photonic devices with advanced packaging technologies presents a major limitation. Coupling light from the package to external fibers, and vice versa, is extremely challenging. Advanced packages such as those implemented using the CoWoS architecture employ mold encapsulation to stabilize and protect the chip-on-wafer assembly before it is attached to the substrate. Interposers are often implemented as large, thin silicon slabs supporting multiple large chips. The chips are often positioned on the interposer in a way that creates a non-uniform weight distribution, which can cause mechanical stress to the interposer, resulting in warpage and cracking. To prevent these negative effects, advanced packages employ mold encapsulation.

Use of mold encapsulation, however, produces variability in the height of the package because the underlying chips may have different heights. Variability in the height of the package translates into variability in the position of the fibers along the vertical direction. This, in turn, produces an offset between the input plane of a fiber and the focal plane of the spot-size converter, resulting in poor coupling efficiency.

To promote PIC-fiber coupling efficiency despite this variability in the height of the encapsulant, the inventors have developed optical couplers configured to provide optical collimation. By employing collimators, a coupler produces an optical beam having rays that are parallel (or quasi-parallel) to one another, making the coupling efficiency less susceptible to variations in the height of the package. The optical couplers described herein are compatible with pluggable connectors, fiber connectors configured to facilitate straightforward connection to the package. This configuration enables optical fibers to be readily removed and replaced, for example in the event of fiber damage, without requiring disposal or replacement of the entire device.

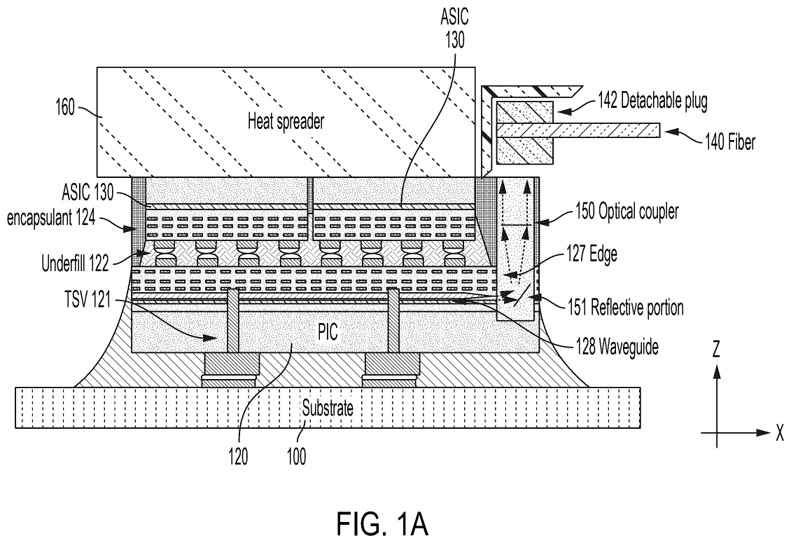

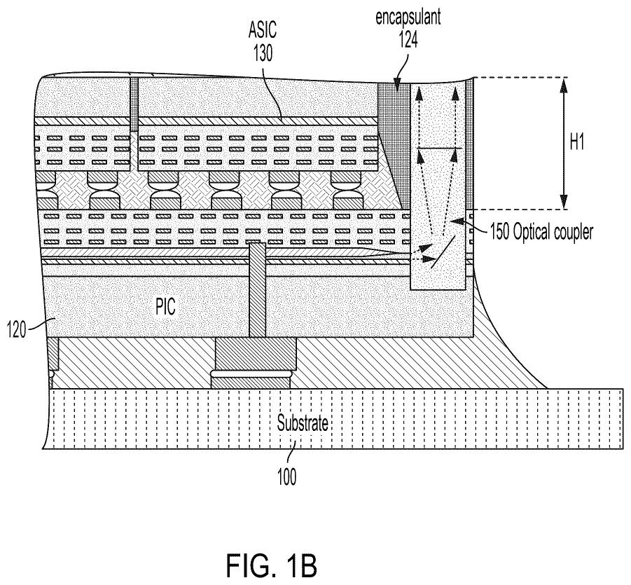

FIG. 1A is a side view of an example of a photonic device implemented in accordance with the techniques described herein. The photonic device of FIG. 1A includes a substrate 100. Substrate 100 may be a printed circuit board (PCB) or an organic substrate, for example. Substrate 100 is configured to route signals generated inside the device to external devices and vice versa. A PIC 120 is disposed on substrate 100, whether directly as shown in FIG. 1A or through an intervening component. PIC 120 may be active in nature in that it may include modulators, photodetectors and/or optical switches. In one example, PIC 120 may be equipped with optical switches to route data to (and from) other devices. PIC 120 may further include a network of waveguides 128. In some embodiments, PIC 120 is made of silicon and PIC waveguides 128 may be made of silicon or silicon nitride. PIC waveguides 128 define a waveguide plane that is parallel to the xy plane of FIG. 1A. PIC waveguides 128 route light inside PIC 120 within the waveguide plane. A plurality of through-silicon vias (TSVs) 121 are patterned within PIC 120 and place the electronic circuitry of PIC 120 in electrical communication with substrate 100.

PIC 120 supports one or more ASICs 130. A stack including a PIC and one or more ASICs attached to the PIC is referred to herein as an electronic-photonic assembly. ASICs of the types described herein are also referred to herein as electronic integrated circuits (EICs). In the arrangement of FIG. 1A, a pair of ASICs is disposed on PIC 120, although the PIC may support any other suitable number of ASICs. Each ASIC may include input/output (I/O) circuitry, control circuitry, processing circuitry and/or memory circuitry. I/O circuitry may include serializers/deserializers (SerDes), for example. Control circuitry may include electronic components configured to interface with active photonic circuitry within PIC 120. For example, the control circuitry may include modulator drivers configured to drive optical modulators and trans-impedance amplifiers configured to detect photocurrents produced by photodetectors. In some embodiments, the control circuitry may further include analog-to-digital converters and digital-to-analog converters. Processing circuitry may be implemented as a central processing unit (CPU), a graphics processing unit (GPU), a field programmable gate array (FPGA), a tensor processing unit (TPU), an accelerator, etc. Memory circuitry may be implemented as a high-bandwidth memory (HBM), for example. An underfill 122 fills the space between PIC 120 and ASICs 130, protecting the bumps, pads or other types of electrical features connecting the top surface of PIC 120 to the bottom surfaces of ASICs 130.

In the arrangement of FIG. 1A, the entire bottom surface of each ASIC is disposed on top of PIC 120. In other embodiments, however, only a portion of an ASIC may be disposed on top of PIC 120; the remainder of the bottom surface of the ASIC may extend beyond the outer edge of the PIC. For example, the remainder of the bottom surface of the ASIC may be disposed on a portion of an underfill (or encapsulant) formed next to PIC 120.

An encapsulant 124 at least partially surrounds ASICs 130. For example, encapsulant 124 may laterally surround a group of ASICs on two, three or four sides. Encapsulant 124 may form a continuous perimeter around the ASICs, while in other implementations may be discontinuous and may surround only some of the sides of the ASICs. Encapsulant 124 may be formed using overmolding techniques (e.g., transfer molding, compression molding or a combination thereof). Encapsulant 124 provides mechanical stability and warpage control, which is particularly desirable in devices in which PIC 120 has been thinned (e.g., resulting in a thickness between 50 μm and 100 μm). The weight of the overlaying ASICs make thin PICS susceptible to warpage, which over time can mechanically damage the chip. Encapsulant 124 reduces this effect.

As further shown in FIG. 1B, the height of encapsulant 124 in the vertical direction (along the z-axis) may be dictated by the vertical extension of ASIC 130. In some embodiments, however, it may be difficult to precisely control the height of encapsulant 124. In FIG. 1B, the height of encapsulant 124 at the edge of the device is referred to as H1. Height H1 may be slightly different from the height of the ASICs, due to spatial variability in the process for removing molding material in excess. As a result, height H1 may be slightly different from its nominal value. As discussed in detail further below, this effect can negatively affect the PIC-fiber coupling efficiency.

Referring back to FIG. 1A, a heat spreader 160 is attached to the top surface of ASICS 130. Heat spreader 160 facilitates distribution of heat generated within the package to the external environment. Additionally, heat spreader 160 covers the ASICs, protecting the package from external agents.

An optical assembly, including a detachable plug 142 and an optical fiber 140 pre-attached to the plug, is connected to the electronic-photonic assembly. Detachable plug 142 may be configured to facilitate straightforward connection between fiber 140 and the electronic-photonic assembly. This configuration enables optical fibers to be readily removed and replaced, for example in the event of fiber damage, without requiring disposal or replacement of the entire device. In some embodiments, detachable plug 142 includes a fiber array unit (FAU), a support configured to hold fibers with a predefined pitch. The FAU may include an array of V-grooves or U-grooves-V-shaped or U-shaped channels that have been etched on a support to hold fibers in place. In this arrangement, detachable plug 142 is disposed on the top surface of encapsulant 124. The fiber is oriented along a plane substantially parallel to the xy plane (e.g., in the lateral direction in FIG. 1A) in the region where the fiber is attached to plug 142. In other arrangements, detachable plug 142 may still be attached to the top surface of encapsulant 124, but the fiber may be oriented along a plane substantially parallel to the zy plane (e.g., in the vertical direction in FIG. 1A), or at a slight angle relative to the z-axis (e.g., less than) 20°. Due to variability in the height of encapsulant 124, the position of detachable plug 142 along the vertical axis may also be subject to variations, resulting in a reduction of the PIC-fiber coupling efficiency. As described in detail further below, some embodiments use a collimator to address this problem.

As shown in FIG. 1A, waveguide 128 ends at or near edge 127 of PIC 120. For example, the end of waveguide 128 may be within 10 μm of edge 127. Therefore, when light reaches the end of waveguide 128, it is emitted outside PIC 120 from edge 127.

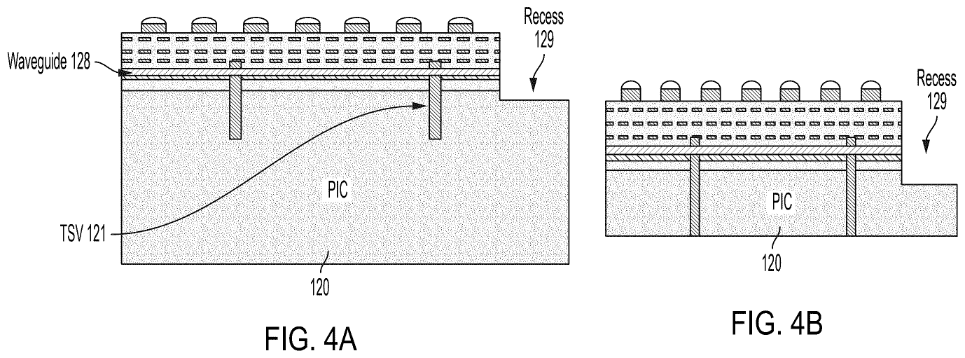

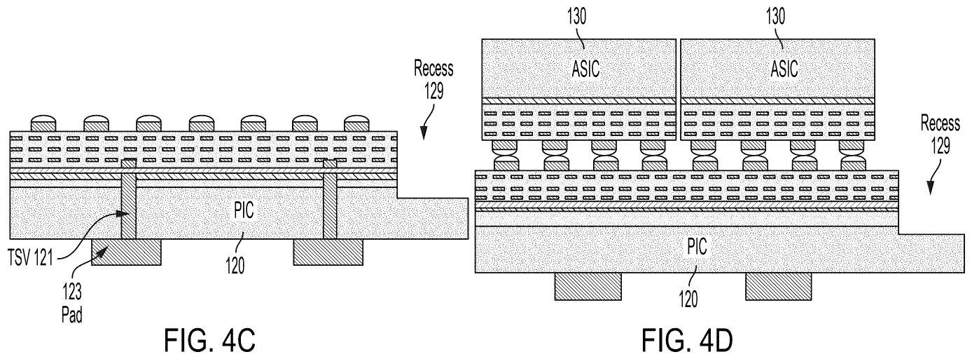

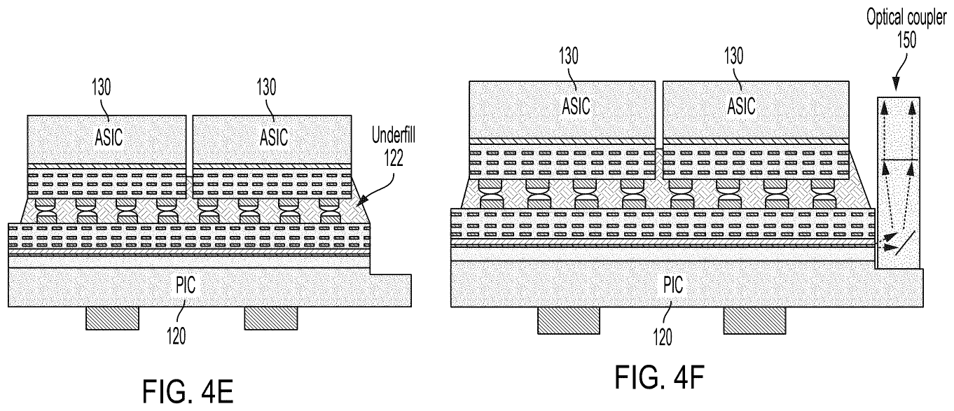

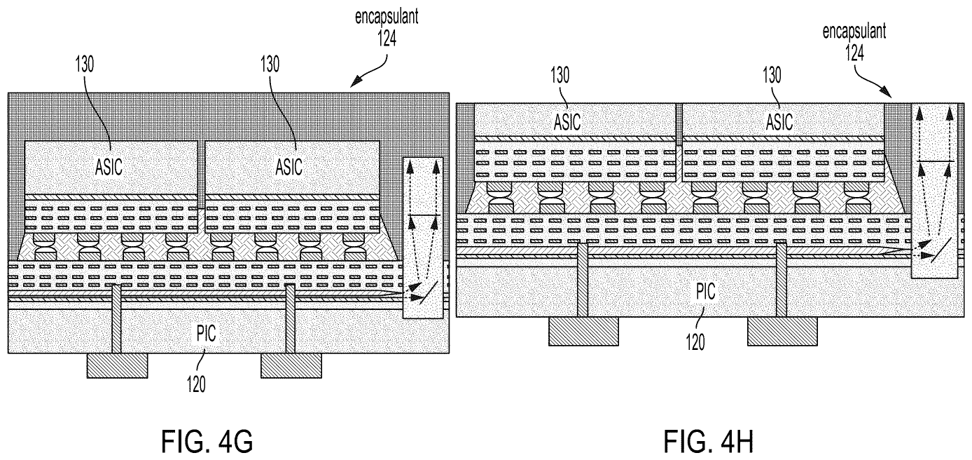

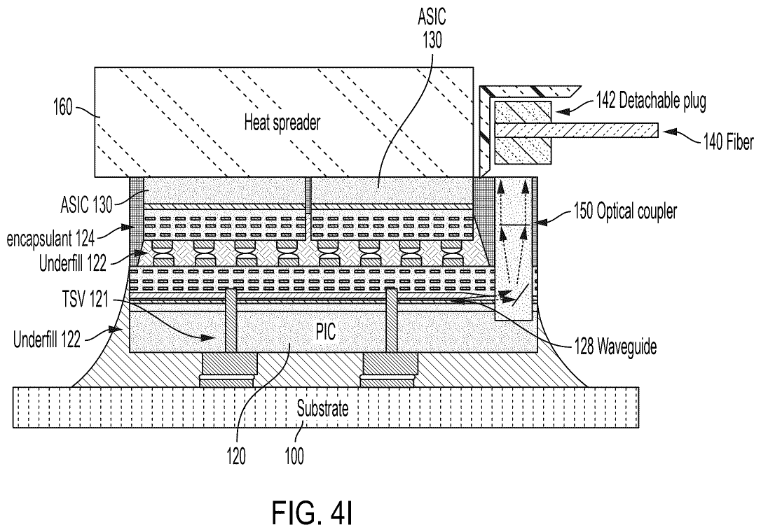

To couple light between PIC 120 and fiber 140, the photonic device includes an optical coupler 150 disposed near edge 127. In this implementation, optical coupler 150 is disposed within a recess that has been formed on the top surface of PIC 120. The location of the recess is described in greater detail below, in connection with FIG. 4A. The recess allows optical coupler 150 to come closer to waveguide 128, enhancing the coupling efficiency. Optical coupler 150 may be made of any material that is transparent to light at the wavelength of interest, including silicon or glass. Optical coupler 150 includes a reflective portion 151 that is configured to reflect light received from waveguide 128 substantially towards the vertical direction (e.g., within 20° of the z-axis), as well as to reflect light received from the substantially vertical direction towards waveguide 128. In some embodiments, reflective portion 151 is angled by approximately 45° relative to the waveguide plane. Reflective portion 151 may be implemented as a conductive surface having a large reflection coefficient (e.g., more than 90%), or may be implemented to operate by total internal reflection.

It should be noted that light emitted through edge 127 has a spatially divergent profile. Inside the waveguide, light propagates as a guide mode. However, when that mode reaches the edge of the PIC, the guided mode transitions into a free-space mode, experiencing diffraction. The higher the degree of confinement of the guided mode, the larger the divergence upon exiting the PIC. Upon reflecting against reflective portion 151, the light continues to diverge.

To compensate for the spatially divergent profile, conventional packages employ lenses configured to focus light onto the input plane of the fiber. However, this approach is not effective in arrangements in which the separation between the edge of the PIC and the input plane of a fiber is unknown. In these arrangements, in fact, the focal plane of the lens may end up being offset from the input plane of the fiber, resulting in poor coupling efficiency. This is the case in the device of FIG. 1A because the height of encapsulant 124—on which detachable plug 142 sits—may not be controlled with a great degree of precision.

To promote PIC-fiber coupling efficiency despite the variability in the height of the encapsulant 124, optical coupler 150 may be configured to provide optical collimation. Collimation is generally referred to as the effect by which a device takes divergent or convergent optical rays and makes them parallel. Collimators, in essence, are devices that straighten optical beams. As used herein, however, the terms “collimator” and “collimation” should be interpreted more broadly to include scenarios in which a beam's angle of divergence (or, in the opposite direction, the angle of convergence) is reduced. In other words, the output beam needs not be perfectly parallel, but may be quasi-parallel. In one example, a collimator may take a beam having an angle of divergence of approximately 10° and may output a beam having an angle of divergence of approximately 3°. In another example, a collimator may take a beam having an angle of divergence of approximately 10° and may output a beam having an angle of convergence of approximately 3°. By reducing the absolute value of the angle, a collimator of the type described herein reduces the coupler's susceptibility to height variability, even if the collimator is not perfect. The collimator of optical coupler 150 may be implemented using one or more lenses. Examples are described further below.

To convert the parallel (or quasi-parallel) beam provided by optical coupler 150 into a beam having a size compatible with the numerical aperture of fiber 140, detachable plug 142 may be equipped with a spot-size converter. In addition, detachable plug 142 may be equipped with a reflective portion configured to reflect light received from reflective portion 151 towards a direction parallel to the xy plane.

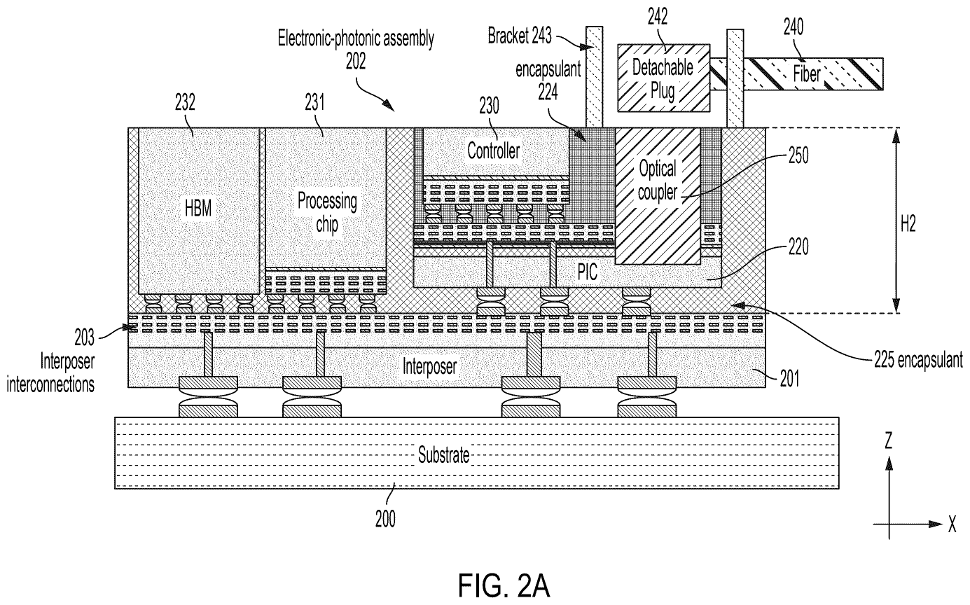

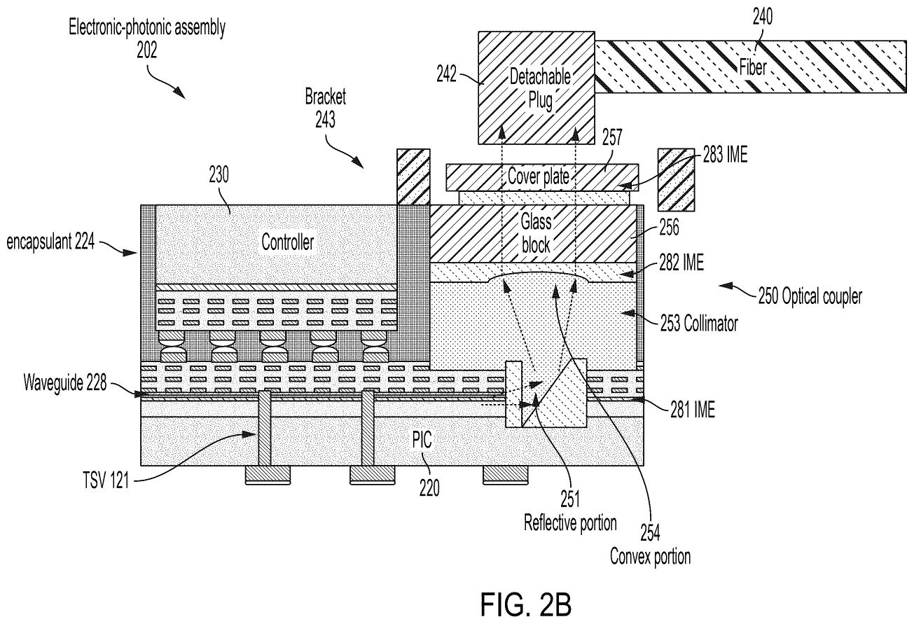

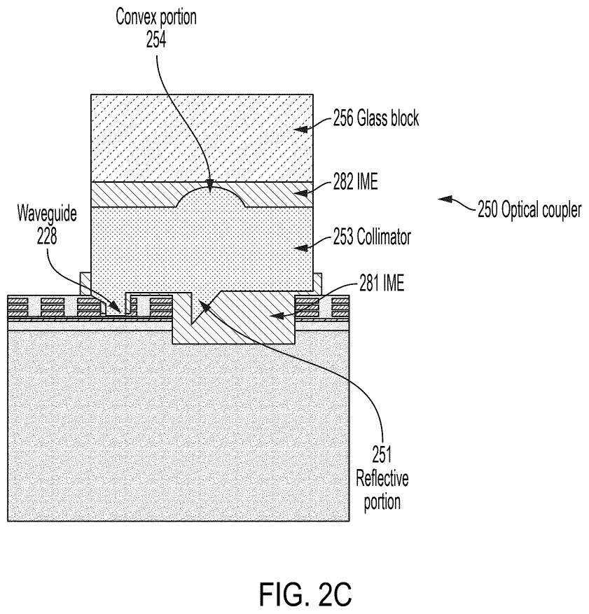

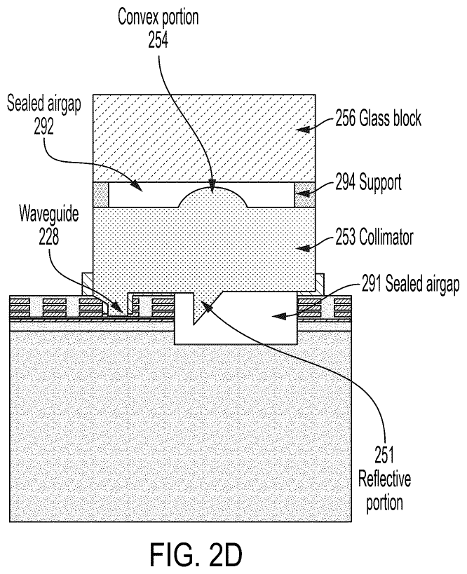

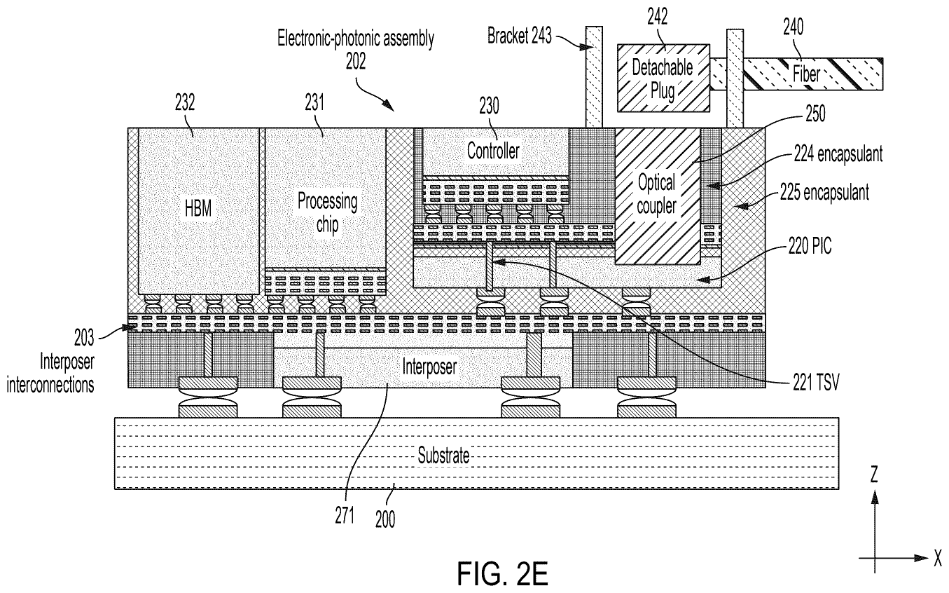

Electronic-photonic assemblies of the types described in connection with FIG. 1A may be used in combination with advanced packaging technologies, including for example with CoWoS. FIG. 2A is a side view of a package including an electronic-photonic assembly disposed on an interposer. The package of FIG. 2A may be implemented in accordance with CoWoS architectures, at least in some embodiments. For example, FIG. 2A may represent a type of CoWoS-S package, in which an interposer is used to interconnect all the packaged chips and assemblies together. Other types of CoWoS-based packaging architectures are also possible, including for example CoWoS-L, in which smaller interposers serve as bridges between selected chips or assemblies. An example of a CoWoS-L package is described below in connection with FIG. 2E.

The package of FIG. 2A includes an interposer 201 attached to a substrate 200. An electronic-photonic assembly 202 is attached to interposer 201. Interposer 201 includes layers of interconnections (interposer interconnections 203) configured to place chips and assemblies in communication with each other. In the example of FIG. 2A, the package includes a processing chip 231 (e.g., a CPU, a GPU, a TPU, an FPGA, etc.), a high-bandwidth memory (HBM) 232 and an electronic-photonic assembly 202, although additional chips and assemblies may be included. Electronic-photonic assembly 202 serves as an optical interface, placing the chips of the package in optical communication with external devices via optical fibers.

Electronic-photonic assembly 202 may be implemented with a similar arrangement as described in connection with FIG. 1A. As such, assembly 202 includes a PIC 220, an ASIC (implemented as a controller 230 in this example), an optical coupler 250, a detachable plug 242, a fiber 240 and an encapsulant 224. A bracket 243 allows detachable plug 242 to be mechanically secured to the package, and easily removed from the package. Controller 230 may include electronic components configured to interface with active photonic circuitry within PIC 220. For example, the control circuitry may include modulator drivers configured to drive optical modulators and trans-impedance amplifiers configured to detect photocurrents produced by photodetectors. Additionally, or alternatively, controller 230 may include serializers/deserializers (SerDes).

An additional encapsulant (encapsulant 225) at least partially surrounds electronic-photonic assembly 202. For example, encapsulant 225 may laterally surround electronic-photonic assembly 202 on two, three or four sides. Encapsulant 225 may form a continuous perimeter around electronic-photonic assembly 202, while in other implementations may be discontinuous and may surround only some of the sides of electronic-photonic assembly 202. Encapsulant 225 may also be formed using overmolding techniques (e.g., transfer molding, compression molding or a combination thereof). While encapsulant 224 provides mechanical stability within electronic-photonic assembly 202, encapsulant 225 provides mechanical stability and warpage control at the package level. In FIG. 2A, the height of encapsulant 225 at the edge of the package is referred to as H2. Similar to height H1 (FIG. 1A), height H2 may be slightly different from its nominal value, leading to variability in the vertical position of detachable plug 242. To address this problem, optical coupler 250 is equipped with a collimator.

FIG. 2B is a side view illustrating a potential implementation of the optical coupler of FIG. 2A, in accordance with some embodiments. FIG. 2C is a side view illustrating the optical coupler of FIG. 2B in additional detail. In this implementation, optical coupler 250 includes a collimator 253, which in turn includes a reflective portion 251 and a convex portion 254. Collimator 253 may be made of silicon or glass, for example. Reflective portion 251 and convex portion 254 are positioned on opposite sides of collimator 253. Reflective portion 251 is on the lower side of collimator 253, near the end of waveguide 228.

Referring to FIG. 2C, reflective portion 251 is configured to reflect light received from waveguide 228 substantially towards the vertical direction (e.g., within 20° of the z-axis), as well as to reflect light received from the substantially vertical direction towards waveguide 228. In some embodiments, reflective portion 251 defines a surface angled by approximately 45° relative to the waveguide plane. Reflective portion 251 may be implemented as a conductive surface having a large reflection coefficient, or may be implemented to operate by total internal reflection. Reflective portion 251 extends in a recess formed on the top surface of PIC 220. An index-matching epoxy (IME) 281 fills the remaining volume of the recess, thereby facilitating optical coupling between the edge of the PIC and collimator 253 while minimizing back-reflections.

Convex portion 254 is positioned at the upper surface of collimator 253. Convex portion 254 defines a curved surface having a curvature designed to collimate the beam reflected by reflective portion 251, thereby producing parallel or quasi-parallel rays. A glass block 256 is disposed on top of collimator 253, facilitating coupling of the collimated beam into the fiber. An IME 282 fills the volume between collimator 253 and glass block 256 to minimize back-reflections. Referring back to FIG. 2B, a glass cover plate 257 is disposed on top of glass block 256, with an IME 283 disposed therebetween to further minimize back-reflections.

The implementation of FIG. 2D is similar to the implementation of FIG. 2C in that it also includes a collimator 253 and a glass block 256. In the implementation of FIG. 2D, however, IMEs 281 and 282 are omitted. Instead, the optical coupler defines sealed airgaps 291 and 292.

FIG. 2E illustrates another example of a CoWoS package. This package is similar to the one illustrated in FIG. 2A, but is arranged as a CoWoS-L package. As such, interposer 271 serves as a bridge between selected components (between electronic-photonic assembly 202 and processing chip 231 in this example).

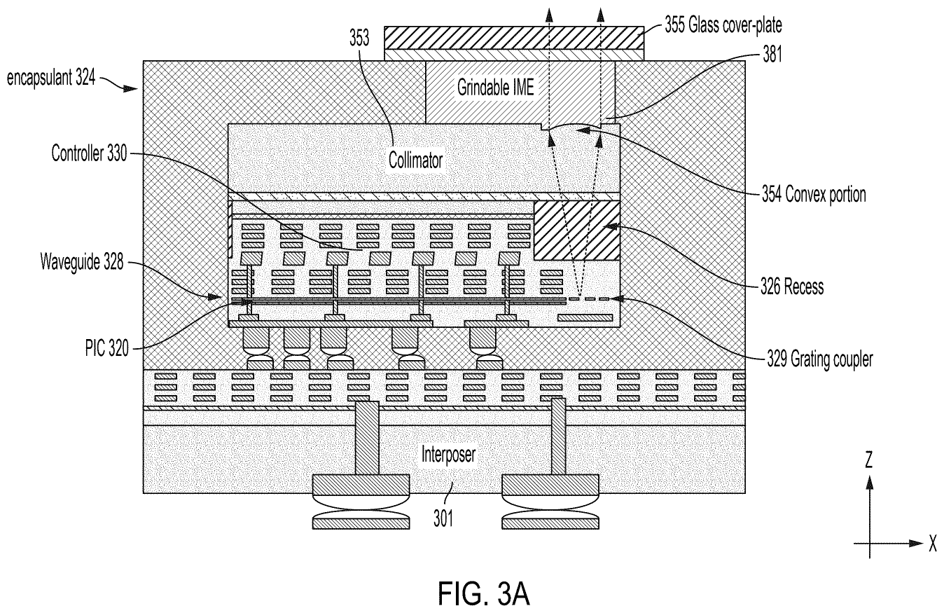

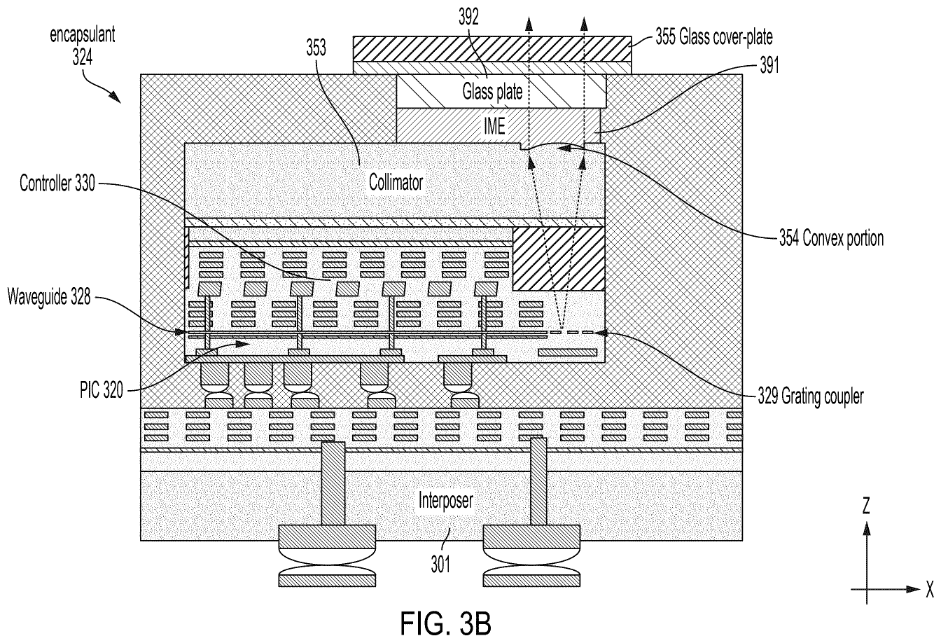

In the packages illustrated in FIGS. 2A-2E, the PIC is configured to emit light laterally, through the end of a waveguide. This arrangement is referred to as side coupling or edge coupling. A reflective portion is used to steer light outside the waveguide plane, towards the upper side of the package. In other arrangements, a PIC may emit light directly outside the waveguide plane, for example using grating couplers. As such, the reflective portion may be omitted (though a further reflective portion may be used to steer light emitted from the grating coupler into a fiber). The packages of FIGS. 3A-3B have PICs including grating couplers.

Referring first to FIG. 3A, this package is similar to the package of FIG. 2A in that it includes an electronic-photonic assembly attached to an interposer 301. The electronic-photonic assembly includes a PIC 320, a controller 330, and an optical coupler having a collimator 353, an IME 381 and a glass cover plate 355. A detachable plug (not shown) receives light provided by the optical coupler. Processing chips and HBMs are omitted from FIG. 3A, but may be included in the package. This package may also be arranged in accordance with the CoWoS architecture.

PIC 320 includes a grating coupler optically coupled to waveguide 328. The grating coupler causes the PIC to emit light outside the waveguide plane, whether in the vertical direction or at a slight angle relative to the z-axis (e.g., less than) 20°. To prevent optical absorption by the overlaying metal layers, a portion of the electronic-photonic assembly has been removed, thus forming a recess 326 on top of grating coupler 329. Recess 326 may be filled with IME in some embodiments. Similar to collimator 253, collimator 353 includes a convex portion 354 having a curvature designed to collimate the beam emitted by grating coupler 329. IME 381 is disposed on top of collimator 353. In some embodiments, the top surface of IME 381 and the top surface of encapsulant 324 may be co-planar. The co-planar arrangement may result from the process of removing part of encapsulant 324 from the upper side of the package. In some embodiments, in fact, IME 381 may be ground together with encapsulant 324, thereby forming a flat surface. In essence, IME 381 defines a transparent conduit through the encapsulant in those embodiments in which the encapsulant covers the electronic-photonic assembly from above, as in FIG. 3A. A glass cover plate 355 is disposed between IME 381 and a detachable plug (not shown).

The package of FIG. 3B is similar to the package of FIG. 3A, but IME 381 has been replaced with a stack including IME 391 and a glass plate 392 attached to the top surface of IME 391. The top surface of glass plate 392 and the top surface of encapsulant 324 may be co-planar.

FIGS. 4A-4I are cross sectional views illustrating a process for fabricating a photonic device, in accordance with some embodiments. The resulting photonic device may be an implementation of the photonic device of FIG. 1A. In some embodiments, the photonic device, once fabricated, may be co-packaged with other electronics chips or assembly, as described above in connection with FIGS. 2A-2E.

The method begins with the fabrication step corresponding to FIG. 4A, in which a PIC 120 is obtained. PIC 120 may have been pre-processed to photolithographically define various photonic and electronic components, such as waveguide 128 and TSV 121. In some embodiments, PIC 120 may further define a recess 129 near an edge of the PIC. Alternatively, if the recess has not been pre-defined, recess 129 may be photolithographically defined as part of the fabrication method described herein, using etching techniques.

In the fabrication step corresponding to FIG. 4B, the substrate of PIC 120 is ground. As a result, TSVs 121 are exposed at the lower surface of PIC 120. In the fabrication step corresponding to FIG. 4C, conductive pads 123 are formed on the ground surface of PIC 120. Pads 123 are electrically coupled to TSVs 121, thereby providing electrical access to the electronic circuitry of PIC 120 from the lower surface.

In the fabrication step corresponding to FIG. 4D, ASICs 130 are attached to PIC 120. In the fabrication step corresponding to FIG. 4E, an underfill 122 is formed between ASICs 130 and PIC 120. In the fabrication step corresponding to FIG. 4F, an optical coupler 150 is attached to PIC. In some embodiments, optical coupler 150 is disposed inside recess 129, allowing optical coupler 150 to come closer to the end of waveguide 128.

In the fabrication step corresponding to FIG. 4G, overmolding is performed on the photonic device to form an encapsulant 124. At this stage, encapsulant 124 may completely enclose the electronic-photonic assembly, thereby blocking optical access to and from PIC 120. In the fabrication step corresponding to FIG. 4H, part of the encapsulant is removed to create optical access to and from the PIC. By removing at least a portion of the encapsulant that covers the optical coupler, this step exposes the optical coupler to air. The final height of encapsulant 124 may exhibit a certain degree of variability, especially at the edge of the device. As such, the position of detachable plug 142 along the vertical direction may also be subject to variability. As described above, to address this problem, optical coupler 150 is configured to provide optimal collimation. In the fabrication step corresponding to FIG. 4I, detachable plug 142 and heat spreader 160 are attached to the electronic-photonic assembly.

Having thus described several aspects and embodiments of the technology of this application, it is to be appreciated that various alterations, modifications, and improvements will readily occur to those of ordinary skill in the art. Such alterations, modifications, and improvements are intended to be within the spirit and scope of the technology described in the application. It is, therefore, to be understood that the foregoing embodiments are presented by way of example only and that, within the scope of the appended claims and equivalents thereto, inventive embodiments may be practiced otherwise than as specifically described. In addition, any combination of two or more features, systems, articles, materials, and/or methods described herein, if such features, systems, articles, materials, and/or methods are not mutually inconsistent, is included within the scope of the present disclosure.

Also, as described, some aspects may be embodied as one or more methods. The acts performed as part of the method may be ordered in any suitable way. Accordingly, embodiments may be constructed in which acts are performed in an order different than described, which may include performing some acts simultaneously, even though shown as sequential acts in illustrative embodiments.

All definitions, as defined and used herein, should be understood to control over dictionary definitions, definitions in documents incorporated by reference, and/or ordinary meanings of the defined terms.

The indefinite articles “a” and “an,” as used herein in the specification and in the claims, unless clearly indicated to the contrary, should be understood to mean “at least one.”

The phrase “and/or,” as used herein in the specification and in the claims, should be understood to mean “either or both” of the elements so conjoined, i.e., elements that are conjunctively present in some cases and disjunctively present in other cases.

As used herein in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified.

The terms “approximately” and “about” may be used to mean within ±20% of a target value in some embodiments, within ±10% of a target value in some embodiments, within ±5% of a target value in some embodiments, and yet within ±2% of a target value in some embodiments. The terms “approximately” and “about” may include the target value.

As used herein, terms such as “above,” “below,” “over,” “under,” “adjacent,” “upper,” “top,” “lower,” “bottom,” “vertical,” “horizontal,” “lateral,” and similar positional or directional descriptors are used solely to describe the relative arrangement and orientation of features as illustrated in the drawings and are not intended to be limiting. Such terms do not require any particular orientation of the device in use, manufacture, or operation, and the described features may be oriented in any direction without departing from the scope of the present disclosure. Moreover, these terms are not intended to imply any absolute position, gravitational reference, or fixed spatial relationship, and components described as being positioned using positional or directional descriptors may be arranged in different relative positions, including inverted, rotated, or otherwise reoriented configurations, while still performing the same function in substantially the same way to achieve substantially the same result.

What is claimed is:

1. A photonic device, comprising:
an electronic-photonic assembly comprising:
a photonic integrated circuit (PIC) comprising a waveguide defining a waveguide plane;
an electronic integrated circuit (EIC) attached to the PIC; and
an encapsulant at least partially encapsulating the EIC;
an optical coupler attached to the PIC, wherein the optical coupler is configured to collimate, in a first direction that is angled relative to the waveguide plane, light emitted by the PIC upon being guided by the waveguide; and
an optical assembly comprising a detachable plug and a fiber attached to the detachable plug, wherein the optical assembly is positioned to receive the collimated light from the optical coupler.

2. The photonic device of claim 1, wherein the optical assembly is disposed on a top surface of the encapsulant.

3. The photonic device of claim 1, wherein the optical coupler comprises:
a reflective portion configured to reflect the light emitted by the PIC in the first direction; and
a convex portion configured to perform the collimation.

4. The photonic device of claim 3, wherein the PIC defines a recess near an end of the waveguide, and wherein the reflective portion extends into the recess.

5. The photonic device of claim 4, further comprising an index-matching epoxy disposed in the recess.

6. The photonic device of claim 2, wherein the reflective portion comprises a surface that is angled by approximately 45° relative to the waveguide plane.

7. The photonic device of claim 1, wherein the optical coupler extends through the encapsulant.

8. The photonic device of claim 1, wherein the PIC further comprises a grating coupler optically coupled to the waveguide and configured to emit light received from the waveguide in the first direction, wherein the optical coupler is configured to collimate the light emitted by the grating coupler.

9. The photonic device of claim 8, further comprising an index-matching epoxy disposed between the optical coupler and the optical assembly.

10. The photonic device of claim 9, wherein the index-matching epoxy has a surface that is co-planar with a surface of the encapsulant.

11. The photonic device of claim 9, further comprising a glass plate disposed between the index-matching epoxy and the optical assembly, wherein the glass plate has a surface that is co-planar with a surface of the encapsulant.

12. A photonic device, comprising:
a chip-on-wafer-on-substrate (CoWoS) package comprising an interposer and an electronic-photonic assembly disposed on the interposer, the electronic-photonic assembly comprising:
a photonic integrated circuit (PIC) having a first side and a second side opposite the first side, wherein the first side of the PIC is attached to the interposer, and wherein the PIC comprises a waveguide defining a waveguide plane;
a first electronic integrated circuit (EIC) attached to the second side of the PIC; and
a first encapsulant at least partially surrounding the first EIC;
an optical coupler attached to the PIC, wherein the optical coupler is configured to collimate, in a first direction that is angled relative to the waveguide plane, light emitted by the PIC upon being guided by the waveguide;
an optical assembly comprising a detachable plug and a fiber attached to the detachable plug, wherein the optical assembly is positioned to receive the collimated light from the optical coupler; and
a second encapsulant at least partially surrounding the electronic-photonic assembly.

13. The photonic device of claim 12, further comprising a second EIC and a third EIC disposed on the interposer, wherein the interposer places the electronic-photonic package in electrical communication with at least one between the second and third EICs.

14. The photonic device of claim 13, wherein:
the first EIC comprises electronic circuitry configured to control active photonic circuitry of the PIC,
the second EIC comprises a processing chip, and
the third EIC comprises a high-bandwidth memory.

15. The photonic device of claim 12, wherein the optical coupler comprises:
a reflective portion configured to reflect the light emitted by the PIC in the first direction; and
a convex portion configured to perform the collimation.

16. The photonic device of claim 15, wherein the PIC defines a recess near an end of the waveguide, and wherein the reflective portion extends into the recess.

17. The photonic device of claim 12, wherein the PIC further comprises a grating coupler optically coupled to the waveguide and configured to emit light received from the waveguide in the first direction, wherein the optical coupler is configured to collimate the light emitted by the grating coupler.

18. A method for fabricating a photonic device, comprising:
forming an electronic-photonic assembly by attaching an electronic integrated circuit (EIC) to a photonic integrated circuit (PIC) having a waveguide;
attaching an optical coupler comprising a collimator to the PIC so that the collimator is optically coupled to the waveguide;
forming an encapsulant by overmolding the electronic-photonic assembly;
exposing the optical coupler to air by removing at least a portion of the encapsulant that covers the optical coupler; and
attaching an optical assembly to the electronic-photonic assembly, the optical assembly comprising a detachable plug and a fiber attached to the detachable plug.

19. The method of claim 18, wherein the PIC defines a recess near an end of the waveguide, and wherein attaching the optical coupler to the PIC comprises placing the optical coupler in the recess.

20. The method of claim 18, wherein removing at least a portion of the encapsulant that covers the optical coupler comprises performing a grinding process on the electronic-photonic assembly.
